(19) United States
(12) Patent Application Publication
(10) Pub. No.: US 2026/0271287 A1
(43) Pub. Date: Sep. 10, 2026

(54) SEMICONDUCTOR DEVICES

(71) Applicant: SAMSUNG ELECTRONICS CO., LTD., Suwon-si (KR)

(72) Inventors: Jeongsu Kim, Suwon-si (KR); Jinwoo Han, Suwon-si (KR)

(73) Assignee: SAMSUNG ELECTRONICS CO., LTD., Suwon-si (KR)

(21) Appl. No.: 19/535,648

(22) Filed: Feb. 10, 2026

(30) Foreign Application Priority Data
Mar. 6, 2025 (KR) 10-2025-0028696

(51) Int. Cl. H10B 43/10; H10B 43/35; H10W 20/20

(52) U.S. Cl. CPC H10B 43/10; H10B 43/35; H10W 20/20

(57) ABSTRACT

A semiconductor device includes a first structure including a memory cell region, and a second structure that overlaps the first structure in a vertical direction and includes a peripheral circuit region. The first structure includes memory cells disposed on the memory cell region, and a cell routing interconnection structure. The second structure includes a semiconductor body, a rear insulating layer, element isolation patterns that define respective peripheral active regions of the semiconductor body, peripheral transistors, each including a first peripheral source/drain and a second peripheral source/drain disposed within the peripheral active regions, a first through-insulating pattern that penetrates through the semiconductor body, and first through-plugs that penetrate through the first through-insulating pattern. The first through-plugs are spaced apart from each other in a horizontal direction and are electrically connected to the cell routing interconnection structure.

### CROSS-REFERENCE TO RELATED APPLICATION

This application claims priority to Korean Patent Application No. 10-2025-0028696 filed on March 6, 2025 in the Korean Intellectual Property Office, the disclosure of which being incorporated by reference herein in its entirety.

### BACKGROUND

As demand for high performance, high speed, and/or multi-functionality of semiconductor devices increases, the integration of semiconductor devices has increased. In the case of related art two-dimensional or planar semiconductor devices, the integration is mainly determined by the area covered by the unit memory cell array region, and is therefore affected by the level of fine pattern formation technology. Accordingly, three-dimensional semiconductor devices including memory cells arranged three-dimensionally have been proposed.

### SUMMARY

It is an aspect to provide a semiconductor device having improved integration of a core/periphery structure controlling an operation of memory cells.

However, the aspect of the present disclosure is not limited to the above-described aspects, and may be variously expanded without departing from the spirit and domain of the present disclosure.

According to an aspect of one or more embodiments, a semiconductor device may comprise a first structure including a memory cell region; and a second structure that overlaps the first structure in a vertical direction and includes a peripheral circuit region. The first structure includes memory cells disposed on the memory cell region, each memory cell including a memory cell transistor and an information storage structure connected to the memory cell transistor; and a cell routing interconnection structure that is electrically connected to the memory cells. The second structure includes a semiconductor body; a rear insulating layer below the semiconductor body; element isolation patterns that define respective peripheral active regions of the semiconductor body; peripheral transistors, each including a first peripheral source/drain, a second peripheral source/drain, a peripheral channel region between the first peripheral source/drain and the second peripheral source/drain, and a peripheral gate disposed on the peripheral channel region, the first peripheral source/drain and the second peripheral source/drain being disposed within the peripheral active regions; a first through-insulating pattern that penetrates through the semiconductor body; and a plurality of first through-plugs that penetrate through the first through-insulating pattern. The plurality of first through-plugs are spaced apart from each other in a horizontal direction and are electrically connected to the cell routing interconnection structure.

According to another aspect of one or more embodiments, a semiconductor device may comprise a first structure including memory cells and a cell routing interconnection structure electrically connected to the memory cells; and a second structure that overlaps the first structure in a vertical direction and that includes a peripheral circuit region. The second structure includes a semiconductor body; a rear insulating layer below the semiconductor body; element isolation patterns that define peripheral active regions of the semiconductor body; peripheral transistors, each including a first peripheral source/drain, a second peripheral source/drain, a peripheral channel region between the first peripheral source/drain and the second peripheral source/drain, and a peripheral gate disposed on the peripheral channel region, the first peripheral source/drain and the second peripheral source/drain being disposed within the peripheral active regions; a first through-insulating pattern that penetrates through the semiconductor body; a second through-insulating pattern that penetrates through the semiconductor body and that is spaced apart from the first through-insulating pattern; a plurality of first through-plugs that penetrate through the first through-insulating pattern and that are spaced apart from each other in a horizontal direction; and a plurality of second through-plugs that penetrate through the second through-insulating pattern and that are spaced apart from each other in the horizontal direction. The number of the first through-plugs is different from the number of the second through-plugs.

According to yet another aspect of one or more embodiments, a semiconductor device may comprise a first structure that includes a memory cell region and a pad region adjacent to the memory cell region, the first structure having an upper surface on which cell bonding pads are disposed; and a second structure that includes a peripheral circuit region that overlaps the first structure in a vertical direction, the second structure having a lower surface on which peripheral bonding pads that are bonded to the cell bonding pads are disposed. The first structure includes memory cells disposed in the memory cell region, each memory cell including a memory cell transistor and an information storage structure connected to the memory cell transistor; and a cell routing interconnection structure electrically connected to the memory cells. The second structure includes a semiconductor body; a rear insulating layer below the semiconductor body; element isolation patterns that define peripheral active regions of the semiconductor body; and peripheral transistors, each including a first peripheral source/drain, a second peripheral source/drain, a peripheral channel region between the first and peripheral source/drain and the second peripheral source/drain, and a peripheral gate disposed on the peripheral channel region, the first peripheral source/drain and the second peripheral source/drain being disposed in the peripheral active regions; a first through-insulating pattern that penetrates through the semiconductor body and that overlaps the memory cell region in the vertical direction; a second through-insulating pattern that penetrates through the semiconductor body and that overlaps the pad region in the vertical direction; a plurality of first through-plugs that penetrate through the first through-insulating pattern and that are spaced apart from each other in a horizontal direction; and a plurality of second through-plugs that penetrate through the second through-insulating pattern and that are spaced apart from each other in the horizontal direction. A gap between the plurality of first through-plugs is different from a gap between the plurality of second through-plugs.

### BRIEF DESCRIPTION OF DRAWINGS

The above and other aspects will be more clearly understood from the following detailed description, taken in conjunction with the accompanying drawings, in which:

FIG. 1 is a perspective view schematically illustrating a semiconductor device according to example embodiments;

FIG. 2 is a circuit diagram of a memory cell of a semiconductor device and a peripheral circuit connected to the memory cell, according to example embodiments ;

FIG. 3 is a perspective view schematically illustrating a cell array structure of a semiconductor device according to an example embodiment;

FIG. 4 is a plan view of a cell array structure of a semiconductor device according to an example embodiment;

FIG. 5 is a vertical cross-sectional view taken along line I-I’ in FIG. 4 according to an example embodiment;

FIG. 6 is a vertical cross-sectional view taken along line II-II’ in FIG. 4 according to an example embodiment;

FIG. 7A is an enlarged view of region A of the semiconductor device of FIG. 5 according to some example embodiments;

FIGS. 7B and 7C are enlarged views of region A of the semiconductor device of FIG. 4 according to some example embodiments;

FIGS. 8A, 8B, 8C, 8D, 8E, 8F, and 8G are cross-sectional views illustrating an example of a method of manufacturing the semiconductor device of FIG. 1, according to some example embodiments; and

FIGS. 9A, 9B, 9C, 9D, 9E, 9F and 9G are cross-sectional views illustrating an example of a method of manufacturing a semiconductor device of FIG. 1, according to some example embodiments.

### DETAILED DESCRIPTION

Hereinafter, example embodiments will be described with reference to the accompanying drawings. For the same components on a drawing, the same reference numerals are used, and duplicate descriptions of identical components are omitted for conciseness. As used in this specification, a phrase using the form “at least one of A, B, or C” includes within its scope “only A”, “only B”, “only C”, “A and B”, “A and C”, “B and C” and “A, B, and C.”

Various semiconductor devices according to example embodiments described below may include a plurality of through-plugs that are connected to peripheral transistors and that penetrate through a through-insulating pattern. Accordingly, the semiconductor devices may have advantages in that a space for forming the peripheral transistors and the through-plugs may be minimized, thereby providing a semiconductor device with improved integration. However, the advantages are not limited to these advantages, and may be variously expanded without departing from the spirit and domain of the present disclosure.

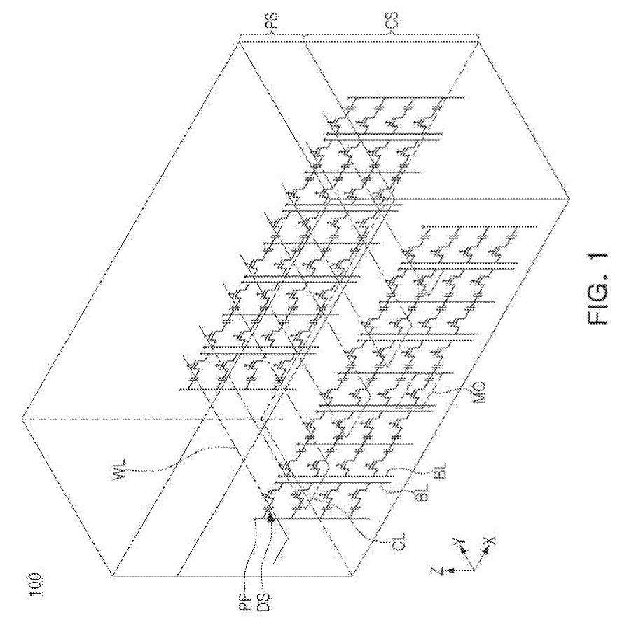

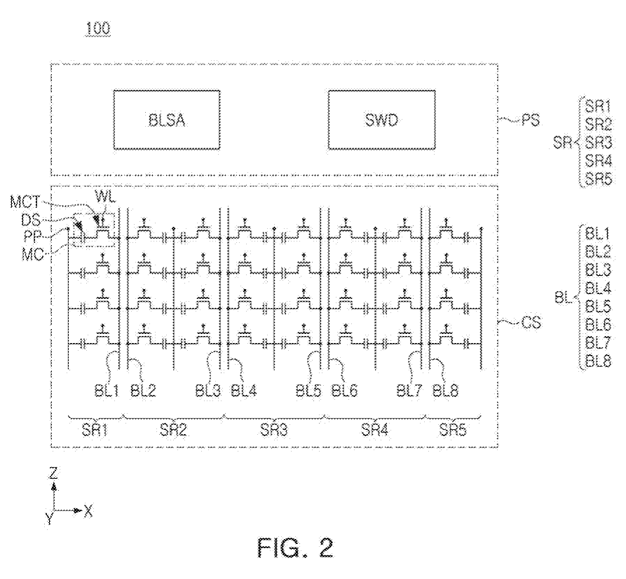

FIG. 1 is a perspective view schematically illustrating a semiconductor device according to example embodiments. FIG. 2 is a circuit diagram of a memory cell a peripheral circuit connected to the memory cell of a semiconductor device, according to example embodiments.

Referring to FIGS. 1 and 2, the semiconductor device 100 may include a cell array structure CS and a peripheral circuit structure PS connected to the cell array structure CS. The peripheral circuit structure PS may overlap the cell array structure CS in a vertical direction (e.g., a Z-direction).

The cell array structure CS may include a plurality of sub-cell array regions SR. The plurality of cell array regions SR may be arranged in a second direction (e.g., a Y-direction). In an example, each of the plurality of cell array regions SR may include a plurality of bit lines BL, a plurality of word lines WL, a plurality of connection lines CL, memory cells MC, and a plurality of plate electrodes PP.

Each of the memory cells MC may include a memory cell transistor MCT and a data storage element DS. One memory cell MC may be disposed between one word line WL and one bit line BL. For example, each memory cell MC may be disposed between a corresponding one of the word lines WL and a corresponding one of the bit lines BL. In an example embodiment, the cell array structure CS of the semiconductor device 100 may correspond to a memory cell array of a Dynamic Random Access Memory (DRAM) device.

The bit lines BL may extend in a third direction (e.g., the Z-direction) and may be spaced apart from each other in a first direction (e.g., an X-direction) and the second direction. The bit lines BL may be vertically oriented from a plane of the cell array structure CS. The bit lines BL may be referred to as vertical bit lines, and a plurality of memory cells MC arranged vertically in the third direction may be connected to one bit line BL. For example, the plurality of memory cells MC that are arranged vertically in the third direction may be connected to a corresponding one of the bit lines BL.

As used herein, the first direction (X direction) and the second direction (Y direction) may be perpendicular to each other. The first and second directions may be collectively referred to as a horizontal direction. The third direction (Z direction) may be referred to as a vertical direction.

The word lines WL may extend in the second direction and may be spaced apart from each other in the third direction. For convenience of explanation, a single layer of word lines WL is illustrated in FIG. 1, but a plurality of layers of word lines WL may be formed. For example, the word lines WL may be spaced apart from each other in the first direction and in the third direction. The word line WL may be horizontally oriented with respect to the plane of the cell array structure CS. The word line WL may be referred to as a horizontal word line, and a plurality of memory cells MC arranged horizontally in the second direction may be connected to one word line WL. For example, the plurality of memory cells MC that are arranged horizontally in the second direction may be connected to a corresponding one of the word lines WL.

The connection lines CL may be spaced apart from each other in the third direction and may connect word lines WL disposed on the same level. For example, the connection lines CL may connect two word lines WL that are adjacent to each other in the first direction.

The memory cell transistor MCT may include a gate, a source, and a drain. The gate may be connected to a word line WL, the source may be connected to a bit line BL, and the drain may be connected to a data storage element DS. The data storage element DS may include a capacitor formed of a lower electrode and an upper electrode and a dielectric layer. In some example embodiments, the memory cell transistor MCT may include a gate all around field effect transistor (GAA FET).

The plate electrodes PP may extend in a third direction and may be electrically connected to the data storage elements DS. The plate electrodes PP may be disposed between memory cells MC that are adjacent to each other in the first direction. The plate electrode PP may extend in the vertical direction and may be electrically connected to the data storage elements DS. The plate electrode PP may be vertically oriented. The plate electrode PP may be referred to as a vertical plate electrode.

The plurality of sub-cell array regions SR of a cell array structure CS may include a first sub-cell region SR1, a second sub-cell region SR2, a third sub-cell region SR3, a fourth sub-cell region SR4, and a fifth sub-cell region SR5. The plurality of bit lines BL may include a first bit line BL1, a second bit line BL2, a third bit line BL3, a fourth bit line BL4, a fifth bit line BL5, a sixth bit line BL6, a seventh bit line BL7, and an eighth bit line BL8. The first bit line BL1 may be disposed on the first sub-cell region SR1. The second and third bit lines BL2 and BL3 may be disposed on the second sub-cell region SR2. The fourth and fifth bit lines BL4 and BL5 may be disposed on the third sub-cell region SR3. The sixth and seventh bit lines BL6 and BL7 may be disposed on the fourth sub-cell region SR4. The eighth bit line BL8 may be disposed on the fifth sub-cell region SR5.

The first and fifth sub-cell regions SR1 and SR5 may be disposed on opposite ends of the second, third and fourth sub-cell regions SR2, SR3 and SR4. Each of the first and fifth sub-cell regions SR1 and SR5 is illustrated as having a structure in which one memory cells MC are stacked in a third direction. However, the present disclosure is not limited thereto. In other embodiment, each of the first to fifth sub-cell regions SR1 to SR5 may have a structure in which two or more memory cell MC arranged side by side in the first direction are stacked in the third direction. In an example embodiment, each of the first, second, third, fourth and fifth sub-cell regions SR1, SR2, SR3, SR4 and SR5 may have a structure in which one memory cell MC is stacked in the third direction. In an example, two memory cells MC may be arranged in a horizontal direction (e.g., in the first direction) as one fair. The two memory cells MC arranged in a horizontal direction as one fair may share the plate electrode PP. For example, the two memory cells MC that are arranged in the horizontal direction as one fair may share a corresponding one of the plate electrodes PP of the plurality of plate electrodes PP.

The peripheral circuit structure PS may include a bit line sense amplifier BLSA and a sub-word line driver SWD. In an example, the bit line sense amplifier BLSA may be electrically connected to bit lines BL of a cell array structure CS as a bit line sense amplifier to operate the bit lines BL. The bit line sense amplifier BLSA may electrically connect one bit line of the bit lines BL and one complementary bit line of the complementary bit lines BL. In an example, the sub-word line driver SWD may be connected to the word lines WL to operate the word lines WL.

In this document, the cell array structure CS may be referred to as a ‘first structure,’ and the peripheral circuit structure PS may be referred to as a ‘second structure.’

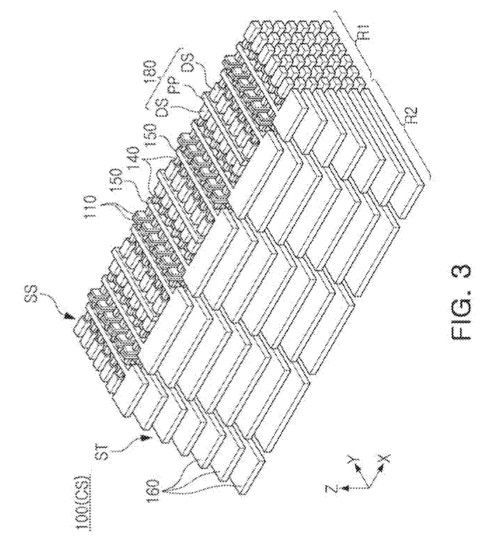

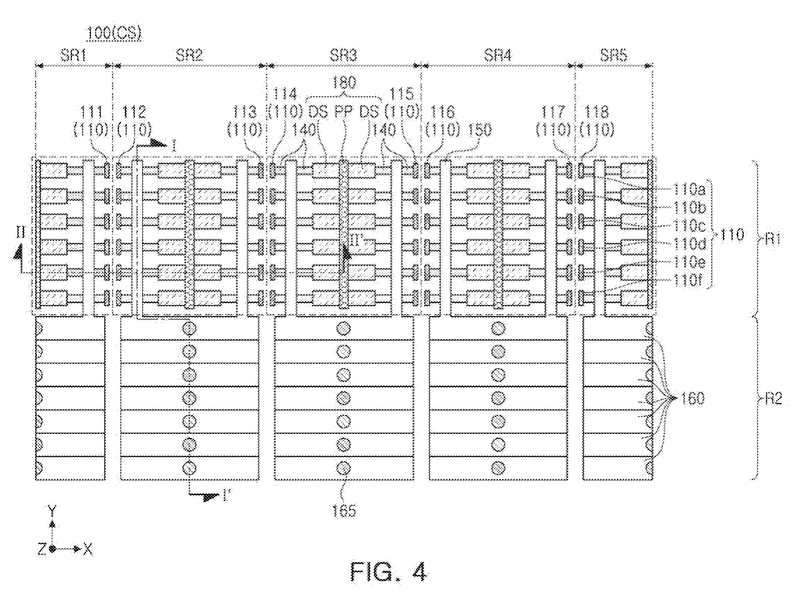

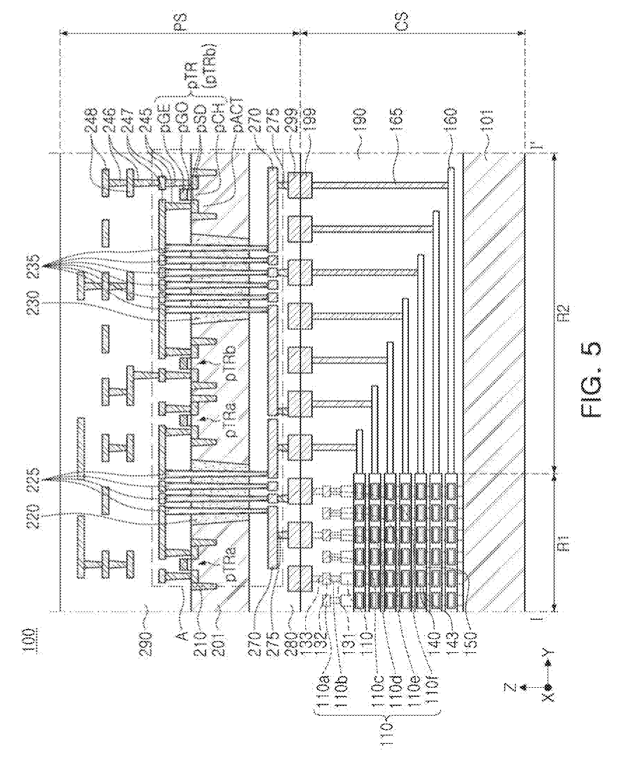

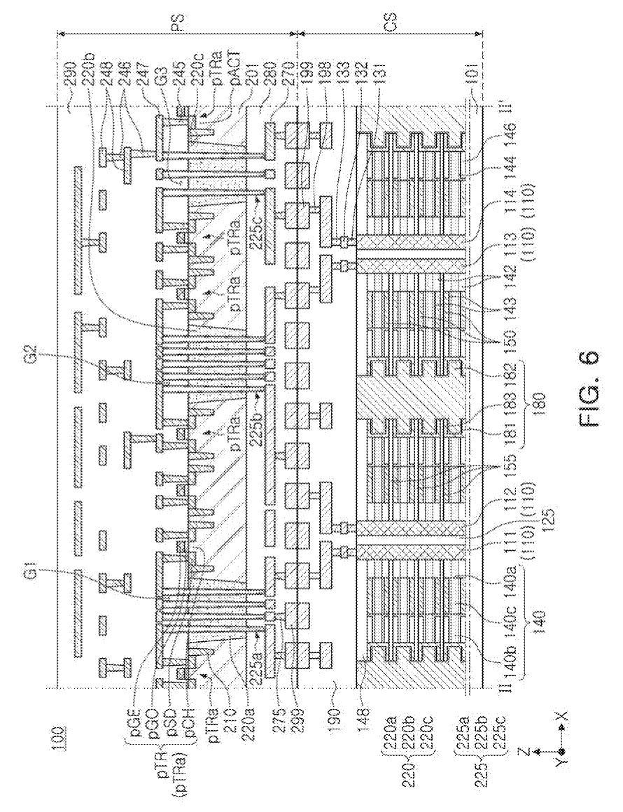

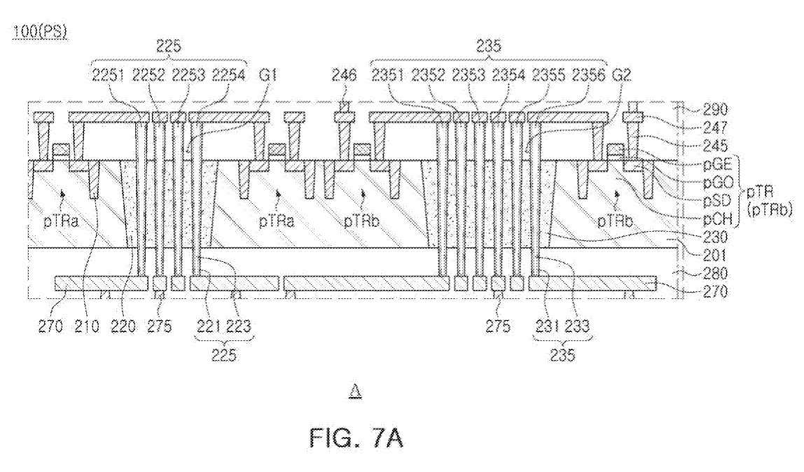

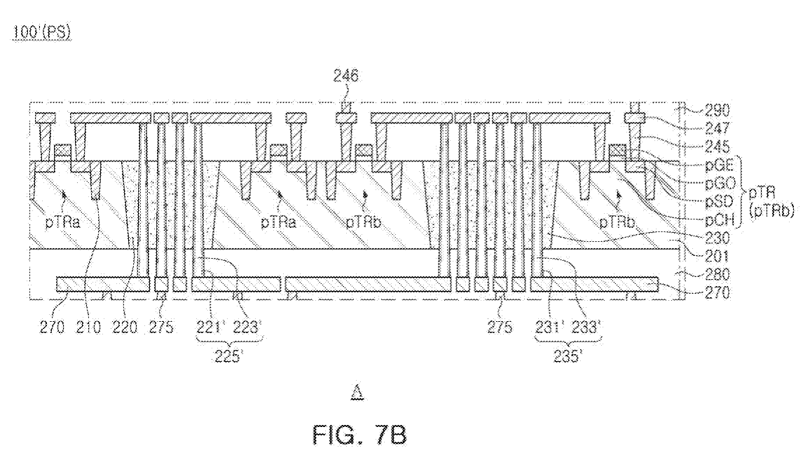

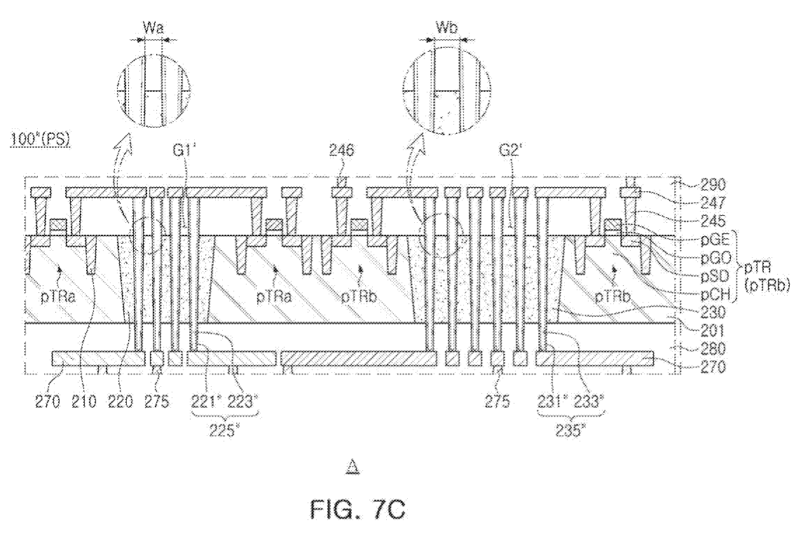

FIG. 3 is a schematic perspective view of a cell array structure of a semiconductor device according to an example embodiment. FIG. 4 is a plan view of a cell array structure of a semiconductor device according to an example embodiment. FIG. 5 is a vertical cross-sectional view illustrating a cross-section taken along line I-I’ of the semiconductor device of FIG. 4 according to an example embodiment. FIG. 6 is a vertical cross-sectional view illustrating a cross-section taken along line II-II’ of the semiconductor device of FIG. 4 according to an example embodiment. FIG. 7A is an enlarged view of region A of the semiconductor device of FIG. 5 according to some example embodiments.

Referring to FIGS. 3 to 6, the semiconductor device 100 may include a cell array structure CS and a peripheral circuit structure PS overlapping the cell array structure CS in a third direction (e.g., a Z-direction).

A substrate 101 of the cell array structure CS may include a memory cell region R1 and a pad region R2. The cell array structure CS of the semiconductor device 100 may include bit lines 110, active patterns 140, gate electrodes 150, and an information storage structure 180, which are disposed on the substrate 101 in the memory cell region R1. The cell array structure CS of the semiconductor device 100 may include gate pads 160 extending from the gate electrodes 150 with different lengths in the pad region R2. In an example, the memory cell region R1 and the pad region R2 may be disposed side by side in a second direction (e.g., a Y-direction).

The semiconductor device 100 may include, for example, a cell array of the DRAM. The bit lines 110 may correspond to the bit lines BL of FIGS. 1 and 2, the gate electrodes 150 may correspond to the word lines WL of FIGS. 1 and 2, and the information storage structure 180 may correspond to the information storage element DS and the plate electrode PP of FIGS. 1 and 2.

The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may be a silicon substrate, a silicon-on-insulator (SOI) substrate, a germanium substrate, a germanium-on-insulator (GOI) substrate, a silicon-germanium substrate, or a substrate including an epitaxial layer.

The bit lines 110 may extend vertically in the third direction on the substrate 101. The bit lines 110 may be spaced apart from each other in a first direction (e.g., an X-direction) and a second direction (e.g., a Y-direction).

One bit line 110 may be electrically connected to a plurality of active patterns 140 stacked in the third direction. For example, each of the bit lines 110 may be electrically connected to corresponding active patterns of the plurality of active patterns 140. For example, the bit line 110 may be electrically connected to first impurity regions 140a. The bit lines 110 may have a line shape, a bar shape, or a pillar shape, which extends in the third direction. The bit lines 110 may include at least one of a doped semiconductor material, a conductive metal nitride, a metal or a metal-semiconductor compound. The bit lines 110 may correspond to the bit lines BL described with reference to FIG. 1.

In an example, as best seen in FIG. 4, the bit lines 110 may include a first bit line 111 disposed in the first sub-cell region SR1, a second bit line 112, and a third bit line 113 that are disposed on the second sub-cell region SR2 and that are spaced apart from each other in the first direction, a fourth bit line 114 and a fifth bit line 115 that are disposed on the third sub-cell region SR3 and that are spaced apart from each other in the first direction, a sixth bit line 116 and a seventh bit line 117 that are disposed on the fourth sub-cell region SR4 and that are spaced apart from each other in the first direction, and an eighth bit line 118 disposed on the fifth sub-cell region SR5. In an example, a pair of bit lines 110 disposed in each of the second, third and fourth sub-cell regions SR2, SR3 and SR4 may be spaced apart from each other in the first direction with the information storage structure 180 interposed therebetween. The first to eighth bit lines 111 to 118 may correspond to the first to eighth bit lines BL1 to BL8 of FIG. 2. In an example, the bit lines 110 disposed in each of the first to fifth sub-cell regions SR1 to SR5 may include a first-first bit line 110a, a first-second bit line 110b, a first- third bit line 110c, a first-fourth bit line 110d, a first-fifth bit line 110e and a first-sixth bit line 110f which are spaced apart from each other in the second direction. Each of the bit lines 110 that are spaced apart from each other in the second direction may be in contact with one end of different active patterns 140.

The active patterns 140 may extend horizontally in the first direction on the substrate 101. The active patterns 140 may be spaced apart from each other in the second direction and the third direction. In the plan view, the active patterns 140 may have a line shape, a bar shape, or a pillar shape, which extends in the first direction and intersects the gate electrodes 150. In an example, the active patterns 140 may include a semiconductor material, for example, silicon, germanium, or silicon-germanium.

Each of the active patterns 140 may include a first impurity region 140a, a second impurity region 140b, and a channel region 140c. The channel region 140c may be disposed between the first impurity region 140a and the second impurity region 140b. The first impurity region 140a may be in contact with the bit line 110 and may be electrically connected to the bit line 110. The second impurity region 140b may be in contact with a first electrode 181 and may be electrically connected to the first electrode 181 of the information storage structure 180. A length of the first impurity region 140a in the first direction and a length of the second impurity region 140b in the first direction may be different from or identical to each other. The channel region 140c may overlap the gate electrodes 150 in the third direction. When the active pattern 140 is formed of a semiconductor material, each of the first impurity region 140a and the second impurity region 140b may include impurities, and the impurities may have an N-type or P-type conductivity type.

At least a portion of the first impurity region 140a may correspond to the first source/drain region of the memory cell transistor MCT of FIG. 1, and at least a portion of the second impurity region 140b may correspond to the second source/drain region of the memory cell transistor MCT of FIG. 1. At least a portion of the channel region 140c may correspond to a channel of the memory cell transistor MCT of FIG. 1. The first impurity region 140a may provide a region for directly connecting the memory cell transistor MCT to the bit line BL, and the second impurity region 140b may provide a region for directly connecting the memory cell transistor MCT to the information storage element DS.

In an example embodiment, the active patterns 140 may include an oxide semiconductor, for example, at least one of hafnium-silicon oxide (HSO), hafnium-zinc oxide (HZO), indium-zinc oxide (IZO), indium-gallium oxide (IGO), indium-tin oxide (ITO), indium-gallium-zinc oxide (IGZO) or indium-tin-zinc oxide (ITZO).

In some example embodiments, the active patterns 140 may include a two-dimensional material (2D material) in which atoms may form a predetermined crystal structure and may form a channel of the transistor. The two-dimensional material layer may include at least one of a transition metal dichalcogenide (TMD) material layer, a black phosphorous material layer, or a hexagonal boron-nitride (hBN) material layer. For example, the two-dimensional material layer may include at least one of BiOSe, Crl, WSe2, MoS2, TaS, WS, SnSe, ReS, β-SnTe, MnO, AsS, P(black), InSe, h-BN, GaSe, GaN, SrTiO or Janus 2D materials, which may form a two-dimensional material.

In some example embodiments, the semiconductor device 100 may further include epitaxial layers respectively connected to the first impurity region 140a and the second impurity region 140b of the active pattern 140 and grown from the active pattern 140.

The gate electrodes 150 may be disposed on the substrate 101 and may extend horizontally in the second direction. The gate electrodes 150 may be spaced apart from each other in the first direction and the third direction. The gate electrodes 150 may be disposed between the channel regions 140c of the active patterns 140. In plan view, the gate electrodes 150 may have a line shape, a bar shape, or a pillar shape, which intersects or crosses the active pattern 140 and which extends in the second direction.

The gate electrodes 150 may include a conductive material, and the conductive material may include at least one of a doped semiconductor material (e.g., doped silicon, doped germanium, or the like), a conductive metal nitride (e.g., titanium nitride, tantalum nitride, tungsten nitride, or the like,), a metal (e.g., tungsten, titanium, tantalum, cobalt, aluminum, ruthenium, or the like.) or a metal-semiconductor compound (e.g., tungsten silicide, cobalt silicide, titanium silicide, or the like.). At least one of the gate electrodes 150 may correspond to the word lines WL described with reference to FIGS. 1 and 2.

In an example embodiment, the gate electrode 150 may be disposed in a gate all around structure surrounding the active pattern 140. In an example embodiment, the gate electrodes 150 may be disposed in a double gate structure. For example, the gate electrodes 150 may be disposed on an upper surface and a lower surface of each active pattern 140, and two gate electrodes 150 adjacent to each active pattern 140 may form one word line WL. In an example embodiment, the gate electrodes 150 may be disposed in a single gate structure. For example, one of the gate electrodes 150 may be disposed adjacently to each active pattern 140, and one gate electrode 150 may form one word line WL.

The cell array structure CS of the semiconductor device 100 may further include a spacer 142, a gate dielectric layer 143, a first capping pattern 144 and a second capping pattern 146.

In an example embodiment, the spacer 142 may be disposed between the gate electrode 150 and the bit line 110. The spacer 142 may overlap the first impurity region 140a of the active pattern 140 in the third direction. The spacer 142 may include at least one of silicon nitride, silicon oxynitride or silicon oxycarbide. For example, the spacer 142 may include silicon nitride.

In an example embodiment, the gate electrode 150 may be arranged in a gate all around structure surrounding the active pattern 140, and the gate dielectric layer 143 may be disposed to surround the active pattern 140 between the active pattern 140 and the gate electrode 150. In an example embodiment, the gate electrodes 150 may be disposed in a double gate structure, and the gate dielectric layer 143 may cover an upper surface and a lower surface of each active pattern 140. In an example embodiment, the gate electrodes 150 may be disposed in a single gate structure, and the gate dielectric layers 143 may cover one of the upper surface and the lower surface of each active pattern 140.

The gate dielectric layer 143 may include at least one of silicon oxide, silicon nitride, a low-κ material, or a high-κ material. The high-κ material may denote a dielectric material having a higher dielectric constant than silicon oxide, and the low-κ material may denote a dielectric material having a lower dielectric constant than a dielectric constant of silicon oxide. The high-κ material may be, for example, a metal oxide or a metal oxynitride. The high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). The gate dielectric layer 143 may be formed as a single layer or multiple layers of the above-described materials.

The first capping pattern 144 and the second capping pattern 146 may be disposed between the gate electrode 150 and the information storage structure 180. The first capping pattern 144 and the second capping pattern 146 may overlap the second impurity region 140b of the active pattern 140 in the third direction. The first capping pattern 144 may be in contact with the second impurity region 140b, the gate electrode 150, and the gate dielectric layer 143. The second capping pattern 146 may be disposed on the first capping pattern 144. The first capping pattern 144 and the second capping pattern 146 may include at least one of silicon nitride, silicon oxynitride or silicon oxycarbide.

The cell array structure CS of the semiconductor device 100 may further include an interlayer insulating layer 155. The interlayer insulating layer 155 may be disposed between the active patterns 140 adjacent to each other in the third direction and between the gate electrodes 150 adjacent to each other in the third direction. The interlayer insulating layer 155 may extend in a horizontal direction (e.g., in the first direction) and may be spaced apart from each other in the third direction. One end of the interlayer insulating layer 155 may be in contact with a side surface of the bit line 110, and the other end of the interlayer insulating layer 155 may be disposed between the first electrodes 181 of the information storage structure 180. An upper surface and a lower surface of the interlayer insulating layer 155 may be in contact with the gate electrode 150, the spacer 142, the first capping pattern 144 and the second capping pattern 146. The interlayer insulating layer 155 may electrically insulate the adjacent gate electrodes 150 from each other.

The interlayer insulating layer 155 may include at least one of silicon oxide, silicon nitride, silicon oxynitride, or silicon oxycarbide. For example, the interlayer insulating layer 155 may include silicon oxide.

The cell array structure CS of the semiconductor device 100 may further include vertical insulating pillars 125. The vertical insulating pillars 125 may be disposed between bit lines 110 adjacent to each other in the first direction. The vertical insulating pillars 125 may extend in the third direction and may be spaced apart from each other in the first direction. The vertical insulating pillars 125 may insulate the adjacent bit lines 110 from each other.

The vertical insulating pillars 125 may include at least one of silicon oxide, silicon nitride, silicon oxynitride, or silicon oxycarbide. For example, the vertical insulating pillars 125 may include silicon oxide.

The information storage structure 180 may include a first electrode 181, a second electrode 182, and a capacitor dielectric 183 between the first and second electrodes 181 and 182. The information storage structure 180 may provide a plurality of information storage elements DS and plate electrodes PP connected to the plurality of information storage elements DS. For example, a portion of the capacitor dielectric 183 and the first electrode 181 and the second electrode 182 that overlaps the first electrode 181 in the third direction may be referred to as an information storage element DS. The plate electrode PP may extend in the third direction and may be electrically connected to the information storage elements DS. For example, the plate electrode PP may be comprised of the second electrode 182.

The information storage structure 180 may be in contact with the second impurity region 140b of the active pattern 140. The information storage structure 180 may be electrically connected to the second impurity region 140b of the active pattern 140. The first electrode 181 may have a cylinder shape, but the shape is not limited thereto, and in some example embodiments, the first electrode 181 may have a pillar shape.

The first electrodes 181 may be in a state in which a node is separated, and for example, the first electrodes 181 may be electrically insulated from each other by the interlayer insulating layer 155. The first electrodes 181 may be referred to as ‘storage node electrodes.’ The first electrodes 181 may include at least one of a doped semiconductor material, a conductive metal nitride, a metal, or a metal-semiconductor compound.

The capacitor dielectric 183 may conformally cover the first electrode 181. The capacitor dielectric 183 may include, for example, at least one of high-κ materials. For example, the capacitor dielectric 183 may include, for example, at least one of zirconium oxide (ZrO₂), aluminum oxide (Al₂O₃), or hafnium oxide (Hf₂O₃).

The second electrode 182 may cover the capacitor dielectric 183 and may extend in the first direction. At least a portion of the second electrode 182 may be referred to as a ‘plate electrode PP.’ The second electrode 182 may include at least one of a doped semiconductor material, a conductive metal nitride, a metal, or a metal-semiconductor compound.

The cell array structure CS of the semiconductor device 100 may further include a capping layer 148. The capping layer 148 may be disposed on a gate electrode 150 in an uppermost portion, among the gate electrodes 150, and may be in contact with side surfaces of the bit line 110 and the information storage structure 180. Each of the capping layers 148 may extend in the first direction and may be spaced apart from each other in the first direction. The capping layers 148 may be coplanar with upper surfaces of the bit lines 110.

The capping layer 148 may include at least one of silicon oxide, silicon nitride, silicon oxynitride, or silicon oxycarbide. For example, the capping layer 148 may include silicon oxide.

The gate pads 160 may be disposed on the substrate 101 and may be connected to the gate electrodes 150. For example, the gate pads 160 may be in contact with ends of the gate electrodes 150, and at least a portion of the gate pads 160 may extend in the first direction. The gate pads 160 may be spaced apart from each other in the third direction. In plan view, the gate pads 160 may have a line shape, a bar shape, or a pillar shape, which extends in the first direction. The gate pads 160 may correspond to the connection lines CL described with reference to FIG. 1.

The gate pads 160 may electrically connect the gate electrodes 150 disposed on the same level for each of the first to fifth sub-cell regions SR1 to SR5. For example, each gate pad 160 may include the same conductive material as the gate electrodes 150. In some example embodiments, the gate pads 160 may be formed integrally with the gate electrodes 150.

The cell array structure CS may include a stack structure SS disposed on the memory cell region R1 and a pad structure ST disposed on the pad region R2 (see FIG. 3). In an example embodiment, components disposed on the substrate 101 on the memory cell region R1 may form the stack structure SS. For example, the stack structure SS may include bit lines 110, active patterns 140, interlayer insulating layers 155, gate electrodes 150, vertical insulating pillars 125, spacers 142, gate dielectric layers 143, first capping patterns 144, second capping patterns 146, capping layers 148, and information storage structures 180. The memory cell region R1 may include first to fifth sub-cell regions SR1 to SR5 disposed in the first direction, and the stack structure SS may be disposed on each of the sub-cell regions SR1 to SR5. The sub-cell regions SR1 to SR5 may be defined as regions adjacent to the pad structure ST in the second direction. The stack structure SS may include two gate electrodes 150 that are adjacent to each other in the first direction and that intersect the active patterns 140, the information storage structure 180 between the two gate electrodes 150, and the bit lines 110 connected to the ends of the active patterns 140.

The gate pads 160 disposed on the substrate 101 on the pad region R2 and spaced apart from each other in the third direction may form the pad structure ST. In an example, in the pad structure ST, the gate pads 160 extending by different lengths in the second direction may form a stepped structure having a staircase form. Due to the stepped structure having the staircase form, a length of the gate pad 160 disposed on a relatively lower side in the second direction may be longer than a length of the gate pad 160 disposed on a relatively upper side in the second direction.

The cell array structure CS of the semiconductor device 100 may further include bit line contact structures 131, 132 and 133, each of the bit lines 110 having corresponding bit line contact structures 131, 132, and 133, word line contact plugs 165 connected to the gate pads 160, and cell bonding pads 199 disposed on the bit line contact structures 131, 132 and 133 and the word line contact plugs 165, as best seen in FIG. 5. The cell array structure CS of the semiconductor device 100 may further include a cell insulating layer 190.

The cell insulating layer 190 may cover the capping layers 148 of the stack structure SS and the bit lines 110 and the gate pads 160 of the pad structure ST. In some example embodiments, the cell insulating layer 190 may be formed of a plurality of layers. The cell insulating layer 190 may include at least one of silicon oxide, silicon nitride, silicon oxynitride, or silicon oxycarbide. The bit line contact structures 131, 132 and 133 and the word line contact plugs 165 may be disposed within the cell insulating layer 190.

The bit line contact structures 131, 132 and 133 may include a first bit line contact via 131 disposed on the bit line 110, a first bit line contact interconnection line 132 disposed on the first bit line contact via 131, and a second bit line contact via 133 disposed on the first bit line contact interconnection line 132. The bit line contact structures 131, 132 and 133 may be disposed on the memory cell region R1. In an example, the first and second bit line contact vias 131 and 133 may have a cylindrical shape, and the first bit line contact interconnection line 132 may have a line shape. In this document, the first and second bit line contact vias 131 and 133 may be referred to as ‘bit line contact plugs.’

The word line contact plugs 165 may be connected to the gate pads 160 of the pad structure ST by vertically penetrating through the cell insulation layer 190. In an example, the pad structure ST may have a staircase-shaped structure, and the word line contact plug 165 may be in contact with an upper surface of the gate pad 160 exposed when viewed in a plan view. In an example, each of the word line contact plugs 165 may have a shape in which a width thereof becomes narrower toward a lower portion. The word line contact plugs 165 may be disposed on the pad region R2. In this document, the word line contact plug 165 may be referred to as a ‘gate contact structure’ or/and a ‘gate contact plug.’

In an example embodiment, a gap between the bit lines 110 that are spaced apart from each other in the second direction may be less than a horizontal length difference between the gate pads 160 adjacent to each other in the second direction. That is, a gap between the first-first to first-sixth bit lines 110a to 110f may be less than the horizontal length difference between the gate pads 160 adjacent to each other in the second direction. In an example, a gap between the first bit line contact vias 131 spaced apart from each other in the second direction may be less than a gap between the word line contact plugs 165 spaced apart from each other in the second direction.

The bit line contact structures 131, 132 and 133 and the word line contact plugs 165 may be referred to as ‘cell routing wiring structures’ in this document.

The cell bonding pads 199 may be disposed on the second bit line contact vias 133 and the word line contact plugs 165. An upper surface of the cell insulation layer 190 and an upper surface of the cell bonding pads 199 may form a coplanar surface.

A peripheral circuit structure PS may be disposed on the memory cell structure CS. The peripheral circuit structure PS may overlap the memory cell structure CS in the third direction.

The peripheral circuit structure PS may include a semiconductor body 201 including peripheral active regions pACT, element isolation patterns 210 defining the peripheral active regions pACT on the semiconductor body 201, peripheral transistors pTR disposed on the semiconductor body 201, a first through-insulating pattern 220 and a second through-insulating pattern 230 that penetrate through the semiconductor body 201, a plurality of first through-plugs 225 that penetrate through the first through-insulating pattern 220, a plurality of second through-plugs 235 that penetrate through the second through-insulating pattern 230, a rear insulating layer 280 disposed below the semiconductor body 201, a first peripheral routing structure 270 and a second peripheral routing structure 275 disposed within the rear insulating layer 280, and peripheral bonding pads 299 disposed on a lower surface of the rear insulating layer 280. In an example embodiment, the peripheral circuit structure PS may further include a front insulating layer 290 disposed on the semiconductor body 201, and second peripheral routing structures 245, 246, 247 and 248 connecting the peripheral transistors pTR and the plurality of first and second through-plugs 225 and 235. In this document, the first peripheral routing structures 270 and 275 may be referred to as ‘first peripheral routing interconnection structures’ and the second peripheral routing structures 245, 246, 247 and 248 may be referred to as ‘second peripheral routing interconnection structures.’

The semiconductor body 201 may include a semiconductor material, such as a group IV semiconductor, a group III-V compound semiconductor, or a group II-VI compound semiconductor. For example, the group IV semiconductor may include silicon, germanium, or silicon-germanium. The semiconductor body 201 may include single crystal silicon.

The element isolation patterns 210 may define peripheral active regions pACT. The element isolation patterns 210 may be disposed between the peripheral transistors pTR, and the element isolation patterns 210 may be spaced apart from each other in a horizontal direction (e.g., in the second direction). Each of the element isolation patterns 210 may have a width that becomes narrower toward a lower portion thereof. The element isolation patterns 210 may have a form embedded in the interior of the semiconductor body 201 from an upper surface of the semiconductor body 201. The element isolation patterns 210 may include silicon oxide and/or silicon nitride.

The peripheral transistors pTR may be disposed on the semiconductor body 201. Each of the peripheral transistors pTR may include peripheral gate structures pGO and pGE disposed on the semiconductor body 201, first and second peripheral source/drain regions pSD disposed within the peripheral active region pACT disposed on both sides of the peripheral gate structures pGO and pGE, and a peripheral channel region pCH between the first and second peripheral source/drain regions pSD. The peripheral gate structures pGO and pGE may include a peripheral gate dielectric layer pGO and a peripheral gate electrode pGE sequentially stacked. In an example embodiment, the peripheral transistors pTR may include a first transistor pTRa and a second transistor pTRb that is distinct from the first transistor pTRa. For example, the first transistor pTRa may be physically separated from a second transistor pTRb in the second direction and may have a different function from the second transistor pTRb. For example, the first transistor pTRa may be a bit line sense amplifier BLSA of FIG. 2, and the second transistor pTRb may be a sub-word line driver SWD of FIG. 2.

The first and second through-insulating patterns 220 and 230 may penetrate through the semiconductor body 201. The first and second through-insulating patterns 220 and 230 may be spaced apart from the element isolation patterns 210 in the horizontal direction. Upper surfaces of the first and second through-insulating patterns 220 and 230 may be coplanar with an upper surface of the semiconductor body 201, and lower surfaces of the first and second through-insulating patterns 220 and 230 may be coplanar with a lower surface of the semiconductor body 201. In an example embodiment, each of the first and second through-insulating patterns 220 and 230 may have a width that narrows toward the lower portion thereof in the third direction. The first through-insulating pattern 220 may be spaced apart from the second through-insulating pattern 230 in the second direction. A width of the first through-insulating pattern 220 in the second direction may be less than a width of the second through-insulating pattern 230 in the second direction. In another embodiment, the first through-insulating pattern 220 may be spaced apart from the second through-insulating pattern 230 in the first direction. A width of the first through-insulating pattern 220 in the first direction may be less than a width of the second through-insulating pattern 230 in the first direction. The peripheral transistors pTR may be disposed between the first through-insulating pattern 220 and the second through-insulating pattern 230. In an example embodiment, the first through-insulating pattern 220 may be disposed between the first peripheral transistors pTRa, and the second through-insulating pattern 230 may be disposed between the second peripheral transistors pTRb.

The first and second through-insulating patterns 220 and 230 may include an insulating material. For example, the first and second through-insulating patterns 220 and 230 may include silicon oxide and/or silicon nitride. However, example embodiments are not limited thereto. In an example embodiment, the first and second through-insulating patterns 220 and 230 may include an insulating material having a low dielectric constant. The low-dielectric constant insulating material may include an insulating material having a lower dielectric constant than a dielectric constant of silicon oxide. For example, the first and second through-insulating patterns 220 and 230 may include tetraethyl orthosilicate (TEOS) or SiOC or SiCOH. The first and second through-insulating patterns 220 and 230 include an insulating material having a low dielectric constant, thereby minimizing interference between the plurality of first through-plugs 225 and minimizing interf erence between the plurality of second through-plugs 235.

The plurality of first through-plugs 225 may penetrate through the first through-insulating pattern 220. The plurality of first through-plugs 225 that penetrate through one first through-insulating pattern 220 may be spaced apart from each other in the horizontal direction (e.g., in the second direction). In an example, each of the plurality of first through-plugs 225 may be connected to the first peripheral transistors pTRa.

The plurality of second through-plugs 235 may penetrate through the second through-insulating pattern 230. The plurality of second through-plugs 235 that penetrate through one second through-insulating pattern 230 may be spaced apart from each other in the horizontal direction (e.g., in the second direction). In an example, each of the plurality of second through-plugs 235 may be connected to the second peripheral transistors pTRb.

An upper surface of each of the plurality of first and second through-plugs 225 and 235 may be disposed on a level higher than a level of an upper surface of the semiconductor body 201, and a lower surface of each of the plurality of first and second through-plugs 225 and 235 may be disposed on a level lower than a level of a lower surface of the semiconductor body 201. The upper surface of each of the plurality of first and second through-plugs 225 and 235 may be disposed within the front insulating layer 290, and the lower surface of each of the plurality of first and second through-plugs 225 and 235 may be disposed within the rear insulating layer 280.

The rear insulating layer 280 may be disposed below the semiconductor body 201 in the third direction. The first peripheral routing structures 270 and 275 may be disposed within the rear insulating layer 280, and the peripheral bonding pads 299 that are connected to the first peripheral routing structures 270 and 285 may be disposed on a lower surface of the rear insulating layer 280. The first peripheral routing structures 270 and 275 may be electrically connected to the plurality of first and second through-plugs 225 and 235. The first peripheral routing structures 270 and 275 may include first peripheral routing interconnection lines 270 in contact with lower surfaces of the plurality of first and second through-plugs 225 and 235 and first peripheral routing vias 275 disposed between the first peripheral routing interconnection lines 270 and the peripheral bonding pads 299. In an example, the first peripheral routing interconnection lines 270 may have a line shape, and the first peripheral routing vias 275 may have a cylindrical shape. Each of the first peripheral routing vias 275 may have a shape that narrows toward an upper portion thereof.

The front insulating layer 290 may be disposed on the semiconductor body 201 to cover the peripheral transistors pTR. The second peripheral routing structures 245, 246,247 and 248 may be disposed within the front insulating layer 290. The second peripheral routing structures 245, 246, 247 and 248 may include peripheral contact plugs 245 connected to peripheral transistors pTR, peripheral interconnection lines 247 disposed on the peripheral contact plugs 245, second peripheral routing vias 246 disposed on the peripheral interconnection lines 247, and second peripheral routing interconnection lines 248 disposed on the second peripheral routing vias 246. The peripheral interconnection lines 247 may electrically connect the peripheral contact plugs 245 and the plurality of first and second through-plugs 225 and 235.

In an example embodiment, each of the plurality of first through-plugs 225 may be electrically connected to the first transistor pTRa through the peripheral contact plugs 245 and the peripheral interconnection lines 247. In an example, each of the plurality of second through-plugs 235 may be electrically connected to the second transistor pTRb through the peripheral contact plug 245 and the peripheral interconnection lines 247.

The memory cell structure CS may be bonded to the peripheral circuit structure PS. The semiconductor device 100 may include the cell bonding pads 199 disposed on an upper surface of the cell array structure CS and the peripheral bonding pads 299 disposed on a lower surface of the peripheral circuit structure PS. In an example, the cell bonding pads 199 disposed on the upper surface of the cell insulation layer 190 may be bonded to the peripheral bonding pads 299 disposed on a lower surface of the rear insulation layer 280, and the cell bonding pads 199 and the peripheral bonding pads 299 may provide a path for electrically connecting the memory cell structure CS and the peripheral circuit structure PS. The cell bonding pads 199 and the peripheral bonding pads 299 may include copper (Cu).

The plurality of first and second through-plugs 225 and 235 may be electrically connected to the cell array structure CS through the first peripheral routing structures 270 and 285. In an example, the plurality of first through-plugs 225 may be connected to the bit lines 110 of the cell array structure CS through the first peripheral routing structures 270 and 285. The plurality of second through-plugs 235 may be connected to the gate pads 160 of the cell array structure CS through the second peripheral routing structures 270 and 285. In an example embodiment, the plurality of first through-plugs 225 may overlap the memory cell region R1 in the third direction, and the plurality of second through-plugs 235 may overlap the pad region R2 in the third direction. However, example embodiments are not limited thereto, and, in some example embodiments, a portion of the plurality of first through-plugs 225 may overlap the pad region R2 in the third direction. In an example embodiment, the first through-insulating pattern 220 through which the plurality of first through-plugs 225 penetrate may overlap the memory cell region R1 in the third direction, and the second through-insulating pattern 230 through which the plurality of second through-plugs 235 penetrate may overlap the pad region R2 in the third direction. However, example embodiments are not limited thereto.

In an example embodiment, the number of the plurality of first through-plugs 225 that penetrate through the first through-insulating pattern 220 may be different from the number of the plurality of second through-plugs 235 that penetrate through the second through-insulating pattern 230. In an example, the plurality of first through-plugs 225 may include four peripheral through-plugs, including a first-first peripheral through-plug 2251, a first-second peripheral through-plug 2252, a first-third peripheral through-plug 2253, and a first-fourth peripheral through-plug 2254. The plurality of second through-plugs 235 may include six peripheral through-plugs, and may include a second-first peripheral through-plug 2351, a second-second peripheral through-plug 2352, a second-third peripheral through-plug 2353, a second-fourth peripheral through-plug 2354, a second-fifth peripheral through-plug 2355, and second-sixth peripheral through-plug 2356. Referring to FIGS. 5 and 7A, the number of the plurality of first through-plugs 225 that penetrate through the first through-insulating pattern 220 may be less than the number of the plurality of second through-plugs 235 that penetrate through the second through-insulating pattern 230. However, example embodiments are not limited thereto, and in some example embodiments, the number of the plurality of first through-plugs 225 that penetrate through one first through-insulating pattern 220 may be equal to the number of the plurality of second through-plugs 235 that penetrate through one second through-insulating pattern 230.

Referring to FIG. 5 and FIG. 7A, a gap G1 between the plurality of first through-plugs 225 may be substantially the same as a gap G2 between the plurality of second through-plugs 235. However, embodiments not limited thereto as will be described with reference to FIG. 7C described below.

Referring to FIG. 6, the first through-insulating pattern 220 may include a first-first through-insulating pattern 220a, a first-second through-insulating pattern 220b, and a first-third through-insulating pattern 220c spaced apart from each other in a horizontal direction (e.g., in the first direction). The first-first through-insulating pattern 220a, the first-second through-insulating pattern 220b and the first-third through-insulating pattern 220c may penetrate through the semiconductor body 201.

In an example embodiment, a plurality of first-first through-plugs 225a may penetrate through the first-first through-insulating pattern 220a, a plurality of first-second through-plugs 225b may penetrate through the first-second through-insulating pattern 220b, and a plurality of first-third through-plugs 225c may penetrate through the first-third through-insulating pattern 220c. In an example, the plurality of first-first through-plugs 225a may be a bundle of through-plugs penetrating through the first-first through-insulating pattern 220a, and may be connected to the first bit line 111 of the first sub-cell region SR1 of the cell array structure CS through the first peripheral routing structures 270 and 275. The plurality of first-second through-plugs 225b may be a bundle of through-plugs penetrating through the first-second through-insulating pattern 220b, and may be connected to the second bit line 112 (or the third bit line 113) of the second sub-cell region SR2 of the cell array structure CS through the first peripheral routing structures 270 and 275. The plurality of first-third through-plugs 225c may be a bundle of through-plugs penetrating through the first-third through-insulating pattern 220c, and may be connected to the fourth bit line 114 of the fourth sub-cell region SR3 of the cell array structure CS through the first peripheral routing structures 270 and 275.

In an example embodiment, the number of each of the plurality of first-first, first-second, and first-third through-plugs 225a, 225b and 225c may be different from each other. In an example, the number of each of the plurality of first-first, first-second and first- third through-plugs 225a,225b and 225c may vary depending on an arrangement of the bit lines 110 and a relationship of the bit lines 110 connected to the same first transistor pTRa, among the bit lines 110. For example, the number of the plurality of first-first through-plugs 225a may be less than the number of the plurality of first-second through-plugs 225b, and may be greater than the number of the plurality of first-third through-plugs 225c.

In an example embodiment, gaps G1, G2, and G3 between each of the plurality of first-first, first-second and first-third through-plugs 225a, 225b and 225c, respectively, may be different from each other. However, example embodiments are not limited thereto, and the gaps G1, G2, and G3 between each of the plurality of first-first, first-second, and first-third through-plugs 225a, 225b and 225c may be identical to each other. For example, the gap G1 between the plurality of first-first through-plugs 225a may be substantially the same as the gap G2 between the plurality of first-second through-plugs 225b, and may be narrower than the gap G3 between the plurality of first-third through-plugs 225c.

Referring to FIG. 7A, each of the plurality of first through-plugs 225 and the plurality of second through-plugs 235 may have a shape in which a width thereof becomes narrower toward a lower portion thereof. In an example embodiment, each of the plurality of first through-plugs 225 may include a first conductive pillar 223 and a first conductive barrier layer 221 covering a side surface and a bottom surface of the first conductive pillar 223. Each of the plurality of second through-plugs 235 may include a second conductive pillar 233 and a second conductive barrier layer 231 covering a side surface and a bottom surface of the second conductive pillar 233. The first and second conductive pillars 223 and 233 may include a metal material such as tungsten (W), aluminum (Al), or copper (Cu). The first and second conductive barrier layers 221 and 231 may include a metal nitride such as titanium nitride (TiN), tantalum nitride, or tungsten nitride.

The semiconductor device 100 according to example embodiments includes a cell array structure CS and a peripheral circuit structure PS disposed on the cell array structure CS, and the peripheral circuit structure PS may include peripheral transistors pTR including a bit line sense amplifier (e.g., a bit line sense amplifier BLSA of FIG. 2) and/or a word line driver (e.g., a word line driver SWD of FIG. 2) disposed on a semiconductor body 201, a first through-insulating pattern 220 penetrating through the semiconductor body 201, and a plurality of first through-plugs 225 connected to the peripheral transistors pTR and penetrating through the first through-insulating pattern 220. Accordingly, a space used to secure a minimum separation distance between each of the peripheral transistors pTR and each of the first through-plugs 225 may be minimized, thereby providing a semiconductor device 100 having improved integration.

FIGS. 7B and 7C are enlarged views of region A of the semiconductor device of FIG. 4 according to some example embodiments.

Referring to FIG. 7B, a semiconductor device 100’ may include a plurality of first and second through-plugs 225’ and 235’. The remaining components except for the plurality of first and second through-plugs 225’ and 235’ may be the same as or may correspond to the components illustrated in FIG. 7A. In an example embodiment, each of the plurality of first and second through-plugs 225’ and 235’ may have a shape that becomes wider toward a lower portion thereof. In an example embodiment, each of the plurality of first through-plugs 225’ may include a first conductive pillar 223’ and a first conductive barrier layer 221’ covering a side surface and an upper surface of the first conductive pillar 223’. Each of the plurality of second through-plugs 235’ may include a second conductive pillar 233’ and a second conductive barrier layer 231’ covering a side surface and an upper surface of the second conductive pillar 233’.

Referring to FIG. 7C, the semiconductor device 100” may include a plurality of first and second through-plugs 225” and 235”. The remaining components except for the plurality of first and second through-plugs 225” and 235” may be the same as or may correspond to the components illustrated in FIG. 7A. A gap G1’ between the plurality of first through-plugs 225” may have a first size Wa, and a gap G2’ between the plurality of second through-plugs 235” may have a second size Wb greater than the first size Wa. For example, the first size Wa may be about 20 nm to about 30 nm or less, and the second size Wb may be greater than about 30 nm. When viewed in plan view, the number of first through-plugs 225” that may be disposed per unit area may be greater than the number of second through-plugs 235” that may be disposed per unit area, the first size Wa that is the gap G1’ between the plurality of first through-plugs 225” may be smaller than the second size Wb that is the gap G2’ between the plurality of the second through-plugs 235”.

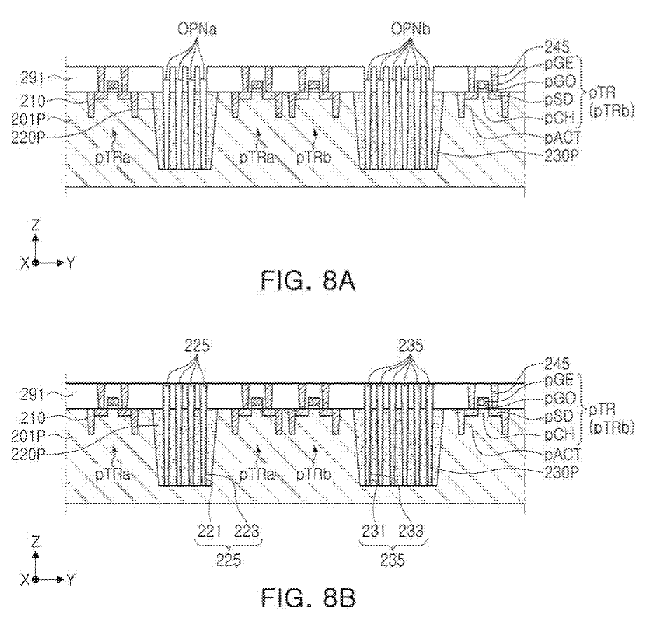

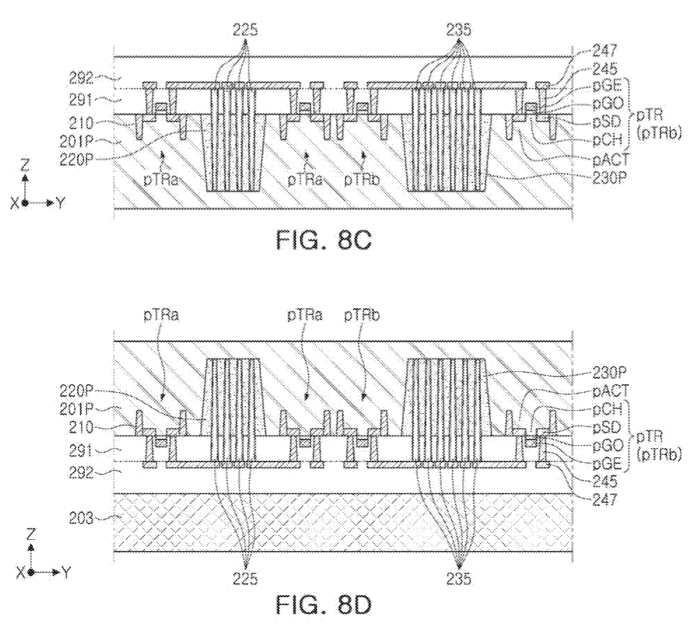

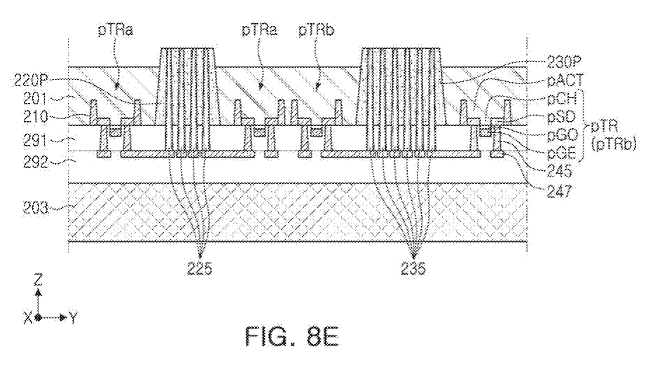

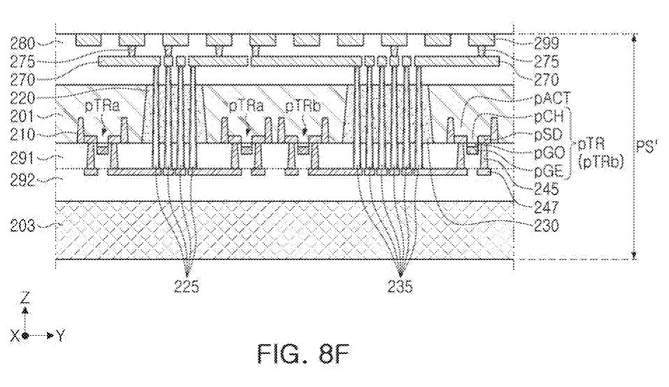

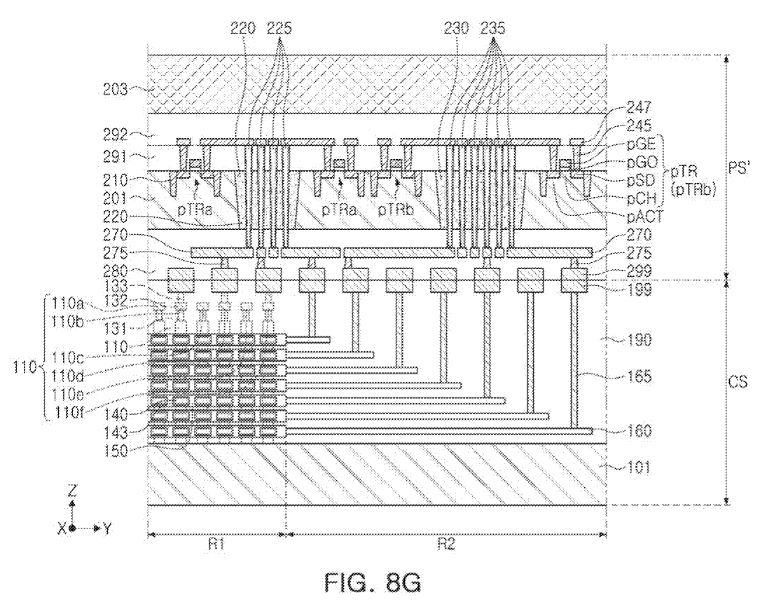

FIGS. 8A, 8B, 8C, 8D, 8E, 8F and 8G are cross-sectional views illustrating a method of manufacturing a semiconductor device of FIG. 1, according to an example embodiment. Referring to FIGS. 8A to 8G, a method of manufacturing a semiconductor device 100 of FIG. 7A will be described.

Referring to FIGS. 8A to 8G, the method according to an embodiment may include preparing a semiconductor substrate 201P, forming a first through-insulating pattern 220 on the semiconductor substrate 201P, forming a through-hole (e.g., a first through-hole OPNa of FIG. 8A) penetrating through the first through-insulating pattern 220 (see FIG. 8A), forming first through-plugs 225 inside the through-holes (e.g., the first through-hole OPNa of FIG. 8A) (see FIG. 8B), reducing a thickness of the semiconductor substrate 201P to expose a portion of a side surface and a lower surface of the first through-plugs 225 (see FIG. 8E), and forming first peripheral routing structures 270 and 275 connected to the first through-plugs 225 on the semiconductor body 201 in which a thickness thereof is reduced (see FIG. 8F).

Referring to FIG. 8A, the method according to some embodiments may include preparing a semiconductor substrate 201P, forming first and second through-insulating patterns 220P and 230P and first and second peripheral transistors pTRa and pTRb on the semiconductor substrate 201P, forming a first peripheral insulating layer 291 covering the first and second peripheral transistors pTRa and pTRb on the semiconductor substrate 201P, forming a peripheral contact plug 245 connected to the first and second peripheral transistors pTRa and pTRb, and forming first and second through-holes OPNa and OPNb penetrating through the first and second through-insulating patterns 220P and 230P and the first peripheral insulating layer 291.

The first and second through-insulating patterns 220P and 230P may be formed by performing an etching operation from the upper surface of the semiconductor substrate 201P to form first and second trenches, and filling the first and second trenches with an insulating material. The insulating material may include silicon oxide, silicon nitride, or an insulating material having a low dielectric constant. In an example, the first through-insulating pattern 220P may be formed between the first peripheral transistors pTRa, and the second through-insulating pattern 230P may be formed between the second peripheral transistors pTRb. In an example, a width of the first through-insulating pattern 220P in the first direction (e.g., an X-direction) may be formed to be less than a width of the second through-insulating pattern 230P in the first direction.

The first peripheral transistor pTRa may form a bit line sense amplifier (e.g., the bit line sense amplifier BLSA of FIG. 2), and the second transistor pTRb may form a sub-word line driver (e.g., the sub-word line driver SWD of FIG. 2). Each of the first and second peripheral transistors pTRa and pTRb may include first and second peripheral source/drain regions pSD disposed within the peripheral active region pACT, a peripheral channel region pCH between the first and second peripheral source/drain regions pSD, a peripheral gate electrode pGE on the peripheral channel region pCH, and a peripheral gate dielectric layer pGO between the peripheral gate electrode pGE and the peripheral channel region pCH. The peripheral active region pACT may be defined by element isolation patterns 210. The first and second peripheral transistors pTRa and pTRb may be covered by the first peripheral insulating layer 291 on the semiconductor substrate 201P. The peripheral contact plugs 245 may penetrate through the first peripheral insulating layer 291 and may be formed on the first and second peripheral source/drain regions pSD of the first and second peripheral transistors pTRa and pTRb.

The first through-holes OPNa may penetrate through the first through-insulating pattern 220P and the first peripheral insulating layer 291 vertically overlapping the first through-insulating pattern 220P, and the second through-holes OPNb may penetrate through the second through-insulating pattern 230P and the first peripheral insulating layer 291 vertically overlapping the second through-insulating pattern 230P. Each of the first through-holes OPNa and the second through-holes OPNb may have a pillar shape in which a width thereof gradually narrows from an upper surface of the first peripheral insulating layer 291 toward a lower surface of the semiconductor substrate 201P.

Referring to FIG. 8B, first and second through-plugs 225 and 235 may be formed by forming the first and second conductive barrier layers 221 and 231 and the first and second conductive pillars 223 and 233 within the first and second through-holes OPNa and OPNb. Upper surfaces of the first and second through-plugs 225 and 235 may be coplanar with upper surfaces of the peripheral contact plugs 245 and upper surface of the first peripheral insulating layer 291.

Referring to FIG. 8C, peripheral interconnection lines 247 may be formed on the peripheral contact plugs 245 and the first and second through-plugs 225 and 235. The peripheral interconnection lines 247 may connect the peripheral contact plugs 245 and the first and second through-plugs 225 and 235. Each of the first through-plugs 225 may be connected to the first peripheral transistor pTRa through the peripheral contact plug 245 and the peripheral interconnection line 247. Each of the second through-plugs 235 may be connected to the second peripheral transistor pTRb through the peripheral contact plug 245 and the peripheral interconnection line 247. The peripheral interconnection lines 247 may be covered by a second peripheral insulating layer 292.

Referring to FIGS. 8C and 8D, after forming a carrier substrate 203 on the second peripheral insulating layer 292, the semiconductor substrate 201P may be inverted to be disposed on the carrier substrate 203. The carrier substrate 203 may be a wafer substrate for protecting an upper surface of the second peripheral insulating layer 292.

Referring to FIGS. 8D, 8E and 8F, a thickness of the semiconductor substrate 201P may be reduced to expose portions of side surfaces and lower surfaces of the first and second through-insulating patterns 220P and 230P. The semiconductor substrate 201P may be reduced in thickness through a Chemical Mechanical Polishing (CMP) or an etch back process. The semiconductor substrate 201P having the reduced thickness may be referred to as a semiconductor body 201. The first and second through-insulating patterns 220P and 230P protruding from one surface of the semiconductor body 201 may be removed to expose portions of side surfaces and lower surfaces of the first and second through-plugs 225 and 235. As the first and second through-insulating patterns 220P and 230P protruding from one surface of the semiconductor body 201 are removed, first and second through-insulating patterns 220 and 230 that are coplanar with the lower surface of the semiconductor body 201 may be formed.

A rear insulating layer 280 may be formed on the lower surface of a semiconductor body 201, first peripheral routing structures 270 and 275 may be formed on the first and second through-plugs 225 and 235, and a peripheral bonding pad 299 may be formed on the first peripheral routing structures 270 and 275 to form a peripheral circuit stack structure PS’. First peripheral routing interconnection lines 270 may be formed on the first and second through-plugs 225 and 235, and first peripheral routing vias may be formed between the first peripheral routing interconnection lines 270 and the peripheral bonding pads 299.

Referring to FIG. 8G, after the peripheral circuit stack structure PS’ is inverted so that the carrier substrate 203 is disposed on the semiconductor body 201, the cell bonding pads 199 of the cell array structure CS and the peripheral bonding pads 299 formed on the lower surface of the rear insulating layer 280 may be bonded to each other.

Next, referring to FIG. 5 together with FIG. 8G, after the carrier substrate 203 is removed, peripheral circuit structure PS may be formed by forming second peripheral routing vias 246 and second peripheral routing interconnection lines 248 on the peripheral interconnection lines 247. Accordingly, a semiconductor device 100 including the cell array structure CS and the peripheral circuit structure PS formed on the cell array structure CS may be formed.

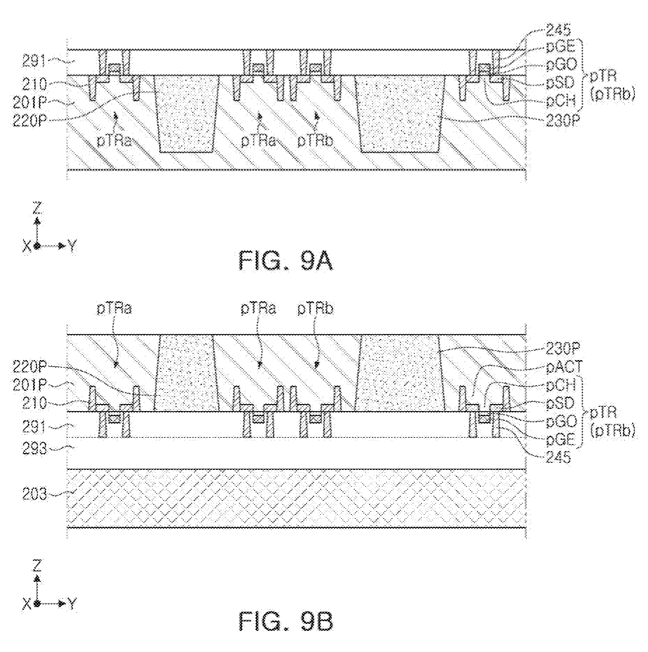

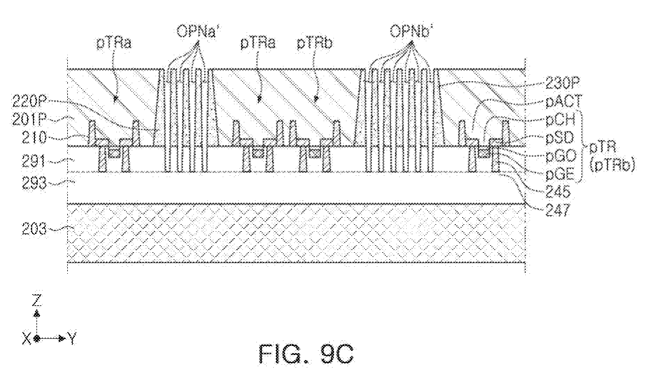

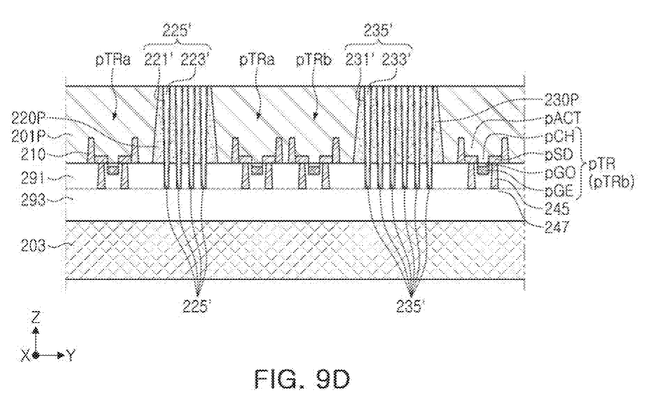

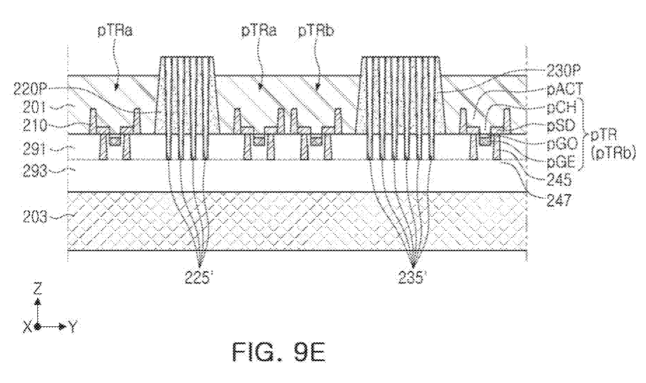

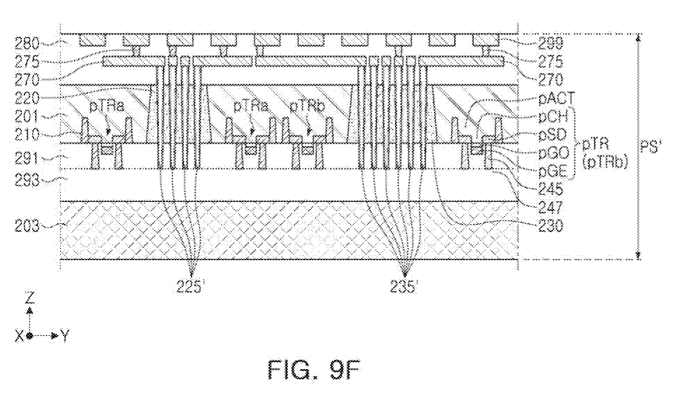

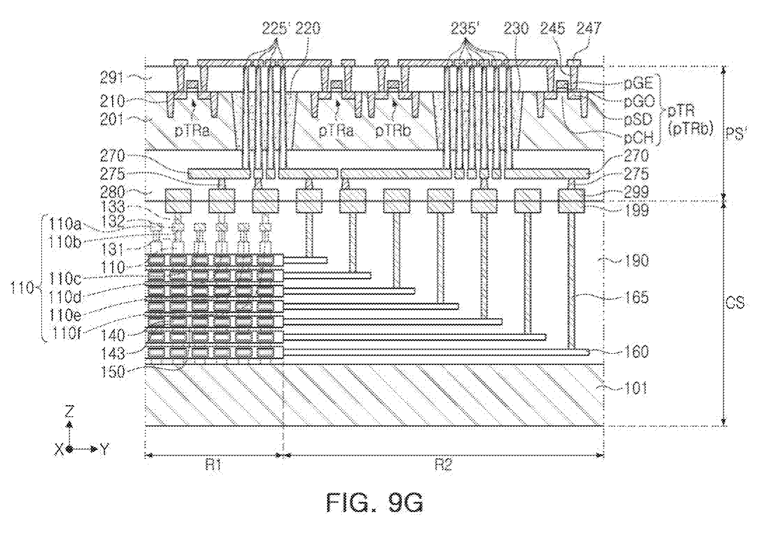

FIGS. 9A, 9B, 9C, 9D, 9E, 9F, and 9G are cross-sectional views illustrating a method of manufacturing a semiconductor device of FIG. 1, according to some example embodiments. Referring to FIGS. 9A to 9G, a method of manufacturing a semiconductor device 100’ of FIG. 7B will be described.

Referring to FIG. 9A, the method according to an example embodiment may include preparing a semiconductor substrate 201P, forming first and second through-insulating patterns 220P and 230P and first and second peripheral transistors pTRa and pTRb on the semiconductor substrate 201P, forming a first peripheral insulating layer 291 covering the first and second peripheral transistors pTRa and pTRb on the semiconductor substrate 201P, and forming a peripheral contact plug 245 connected to the first and second peripheral transistors pTRa and pTRb.

Referring to FIG. 9B, a third peripheral insulating layer 293 and a carrier substrate 203 may be sequentially formed on the first peripheral insulating layer 291 and the peripheral contact plug 245, and then the carrier substrate 203 may be inverted so that the semiconductor substrate 201P is disposed on the carrier substrate 203. The third peripheral insulating layer 293 may include an insulating material different from the first peripheral insulating layer 291.

Referring to FIG. 9C, a thickness of the semiconductor substrate 201P may be reduced to expose the lower surfaces of the first and second through-insulating patterns 220P and 230P, and first and second through-holes OPNa’ and OPNb’ may be formed by penetrating through the first and second through-insulating patterns 220P and 230P and the first peripheral insulating layer 291. A thickness of the semiconductor substrate 201P may be reduced through a Chemical Mechanical Polishing (CMP) process. The first and second through-holes OPNa’ and OPNb’ may etch the first and second through-insulating patterns 220P and 230P and the first peripheral insulating layer 291 from the lower surfaces of the first and second through-insulating patterns 220P and 230P toward the third peripheral insulating layer 293. The third peripheral insulating layer 293 may be exposed through the first and second through-holes OPNa’ and OPNb’. The third peripheral insulating layer 293 may function as an etching stop layer. Each of the first through-holes OPNa’ and the second through-holes OPNb’ may have a pillar shape in which a width thereof becomes narrower from the lower surfaces of the first and second through-insulating patterns 220P and 230P toward the third peripheral insulating layer 293.

Referring to FIG. 9D, first and second through plugs 225’ and 235’ may be formed by forming first and second conductive barrier layers 221’ and 231’ and first and second conductive pillars 223’ and 233’ within the first and second through holes OPNa’ and OPNb’. The first and second through plugs 225’ and 235’ may have a shape in which a width becomes narrower from lower surfaces of the first and second through insulating patterns 220P and 230P toward the third peripheral insulating layer 293.

Referring to FIG. 9E and FIG. 9F, a thickness of the semiconductor substrate 201P may be reduced to expose portions of side surfaces of the first and second through insulating patterns 220P and 230P. The semiconductor substrate 201P having the reduced thickness may be referred to as a semiconductor body 201. The first and second through-insulating patterns 220P and 230P protruding from one surface of the semiconductor body 201 may be removed to expose portions of side surfaces of the first and second through-plugs 225’ and 235’ and lower surfaces thereof. A rear insulating layer 280 may be formed on one surface of the semiconductor body 201 from which the first and second through-plugs 225’ and 235’ protrude, first peripheral routing structures 270 and 275 may be formed on the first and second through-plugs 225’ and 235’, and a peripheral bonding pad 299 may be formed on the first peripheral routing structures 270 and 275, thereby forming a peripheral circuit stack structure PS’.

Referring to FIG. 9G, after the peripheral circuit stack structure PS’ is inverted so that the carrier substrate 203 is disposed on the semiconductor body 201, the cell bonding pads 199 of the cell array structure CS and the peripheral bonding pads 299 formed on the lower surface of the rear insulating layer 280 may be bonded to each other. After the third peripheral insulating layer 293 and the carrier substrate 203 are removed, peripheral interconnection lines 247 may be formed on the peripheral contact plug 245. A peripheral circuit structure PS may be formed by forming second peripheral routing vias (e.g., the second peripheral routing vias 246 of FIG. 5) and second peripheral routing interconnection lines (e.g., the second peripheral routing interconnection lines 248 of FIG. 5) on the peripheral interconnection lines 247. Accordingly, a semiconductor device 100’ including a cell array structure CS and a peripheral circuit structure PS formed on the cell array structure CS may be formed.

Consistent with the above description, according to some aspects of one or more embodiments, a method of manufacturing a semiconductor device may include preparing a semiconductor substrate, forming a first through-insulating pattern on the semiconductor substrate, forming through-holes that penetrate through the first through-insulating pattern, forming first through-plugs within the through-holes, reducing a thickness of the semiconductor substrate to expose a portion of a side surface and a lower surface of the first through-plugs, and forming a first peripheral routing structure that is connected to the first through-plugs whose thickness is reduced, on the semiconductor substrate.

In some example embodiments, the forming the first through-insulating pattern may include forming a first trench that exposes a sidewall and a bottom surface from an upper surface of the semiconductor substrate, and forming an insulating material within the first trench.

In some example embodiments, the method of manufacturing a semiconductor device may further include forming peripheral transistors on an upper surface of the semiconductor substrate, and forming a first peripheral insulating layer that covers the peripheral transistors, on the upper surface of the semiconductor substrate.

According to some example embodiments, the through-holes may penetrate through the first peripheral insulating layer.

According to some example embodiments, the method of manufacturing a semiconductor device may further include forming peripheral contact plugs that penetrate through the first peripheral insulating layer and are connected to the peripheral transistors, wherein upper surfaces of the peripheral contact plugs may be coplanar with an upper surface of the first peripheral insulating layer.

According to some example embodiments, the method of manufacturing a semiconductor device may further include forming peripheral connection interconnection lines that connect the first through-plugs and the peripheral contact plugs, forming a second peripheral insulating layer on the peripheral connection interconnection lines and the first peripheral insulating layer, and forming a second peripheral routing structure that is to the peripheral connection interconnection lines within the second peripheral insulating layer.

According to some example embodiments, the forming through-holes may further include reducing a thickness of the semiconductor substrate so that a lower surface of the first through insulating pattern is exposed, and etching the first through-insulating pattern and the first peripheral insulating layer from a lower surface of the first through-insulating pattern toward the upper surface of the first peripheral insulating layer.

According to some example embodiments, each of the through-holes may have a side surface and a bottom surface that expose the first through-insulating pattern and the first peripheral insulating layer, on the first through-insulating pattern.

According to some example embodiments, the method of manufacturing the semiconductor device may further include forming peripheral bonding pads that are connected to the first peripheral routing structure, preparing a cell structure that includes memory cells, a cell routing interconnection structure that is connected to the memory cells, and cell bonding pads that are connected to the cell routing interconnection structure, and bonding the peripheral bonding pads to the cell bonding pads.

According to some example embodiments, each of the through-holes may have a side surface that exposes the first through-insulating pattern and a bottom surface that exposes the semiconductor substrate below the first through-insulating pattern.

Semiconductor devices according to various example embodiments may include a plurality of through-plugs that are connected to peripheral transistors such as a sense amplifier or a word line driver and that penetrate through a through-insulating pattern such as a deep trench isolation (DTI). Accordingly, the semiconductor devices may have advantages in that a space for forming the peripheral transistors and the through-plugs may be minimized, thereby providing a semiconductor device with improved integration.

However, the advantages are not limited to the above-described advantages, and may be variously expanded without departing from the spirit and domain of the present disclosure.

While example embodiments have been illustrated and described above, it will be apparent to those skilled in the art that modifications and variations may be made within a scope not departing from the spirit and region of the present disclosure as defined by the appended claims.

What is claimed is:

1. A semiconductor device comprising:
a first structure including a memory cell region; and
a second structure that overlaps the first structure in a vertical direction and includes a peripheral circuit region,
wherein the first structure includes:
memory cells disposed on the memory cell region, each memory cell including a memory cell transistor and an information storage structure connected to the memory cell transistor; and
a cell routing interconnection structure that is electrically connected to the memory cells,
wherein the second structure includes:
a semiconductor body;
a rear insulating layer below the semiconductor body;
element isolation patterns that define respective peripheral active regions of the semiconductor body;
peripheral transistors, each including a first peripheral source/drain, a second peripheral source/drain, a peripheral channel region between the first peripheral source/drain and the second peripheral source/drain, and a peripheral gate disposed on the peripheral channel region, the first peripheral source/drain and the second peripheral source/drain being disposed within the peripheral active regions;
a first through-insulating pattern that penetrates through the semiconductor body; and
a plurality of first through-plugs that penetrate through the first through-insulating pattern, and
wherein the plurality of first through-plugs are spaced apart from each other in a horizontal direction and are electrically connected to the cell routing interconnection structure.

2. The semiconductor device of claim 1, wherein the second structure further includes:
a second through-insulating pattern that penetrates through the semiconductor body; and
a plurality of second through-plugs that penetrate through the second through-insulating pattern, that are spaced apart from each other in the horizontal direction, and that are electrically connected to the cell routing interconnection structure, and
wherein the number of the second through-plugs is different from the number of the first through-plugs.

3. The semiconductor device of claim 2, wherein a width of the second through-insulating pattern in the horizontal direction is greater than a width of the first through-insulating pattern in the horizontal direction, and
the number of the plurality of second through-plugs is greater than the number of the plurality of first through-plugs.

4. The semiconductor device of claim 2, wherein a gap between the plurality of first through-plugs is substantially the same as a gap between the plurality of second through-plugs.

5. The semiconductor device of claim 2, wherein the first structure further includes:
a pad region adjacent to the memory cell region, and
gate pads disposed on the pad region and respectively extending from gate electrodes of the memory cell transistors of each of the memory cells, and
wherein the gate pads are spaced apart from each other in the vertical direction and are arranged in a staircase shape.

6. The semiconductor device of claim 5, wherein the cell routing interconnection structure includes:
a bit line contact structure connected to a bit line of the memory cell transistor, and
gate contact structures connected to the gate pads,
wherein the bit line contact structure is connected to the plurality of first through-plugs, and
wherein the gate contact structures are connected to the plurality of second through-plugs.

7. The semiconductor device of claim 6, wherein the first through-insulating pattern overlaps the memory cell region in the vertical direction, and
the second through-insulating pattern overlaps the pad region in the vertical direction.

8. The semiconductor device of claim 6, wherein the number of the second through-plugs is greater than the number of the first through-plugs.

9. The semiconductor device of claim 6, wherein a gap between the plurality of first through-plugs is less than a gap between the plurality of second through-plugs.

10. The semiconductor device of claim 1, wherein the second structure further includes:
a first peripheral routing interconnection structure that is disposed within the rear insulating layer and that is electrically connected to the plurality of first through-plugs; and
peripheral bonding pads that are connected to the first peripheral routing interconnection structure and that are disposed on a lower surface of the rear insulating layer, and
wherein each of the plurality of first through-plugs is connected to the cell routing interconnection structure through the first peripheral routing interconnection structure.

11. The semiconductor device of claim 10, wherein the semiconductor device further includes:
a cell insulating layer that is disposed on the memory cells and that has an upper surface in contact with the lower surface of the rear insulating layer; and
cell bonding pads that are connected to the cell routing interconnection structure and that are disposed on the cell insulating layer and bonded to the peripheral bonding pads.

12. The semiconductor device of claim 10, wherein the semiconductor device further includes:
a front insulating layer disposed on the semiconductor body; and
a second peripheral routing structure that is disposed within the front insulating layer and that is connected to the first peripheral source/drain and to the second peripheral source/drain of the peripheral transistors and to each of the plurality of first through-plugs.

13. The semiconductor device of claim 1, wherein each of the plurality of first through-plugs has a shape in which a width thereof becomes wider toward a lower surface of the rear insulating layer.

14. The semiconductor device of claim 1, wherein each of the memory cells further includes:
active patterns that extend in a first horizontal direction and that are spaced apart from each other in the vertical direction;
bit lines in contact with a first end of the active patterns and extending in the vertical direction, the bit lines being spaced apart from each other in a second horizontal direction that intersects the first horizontal direction; and
gate electrodes that surround the active patterns, that extend in the second horizontal direction, and that spaced apart from each other in the vertical direction, and
wherein the information storage structure is in contact with a second end facing the first end of each of the active patterns.

15. A semiconductor device comprising:
a first structure including memory cells and a cell routing interconnection structure electrically connected to the memory cells; and
a second structure that overlaps the first structure in a vertical direction and that includes a peripheral circuit region,
wherein the second structure includes:
a semiconductor body;
a rear insulating layer below the semiconductor body;
element isolation patterns that define peripheral active regions of the semiconductor body;
peripheral transistors, each including a first peripheral source/drain, a second peripheral source/drain, a peripheral channel region between the first peripheral source/drain and the second peripheral source/drain, and a peripheral gate disposed on the peripheral channel region, the first peripheral source/drain and the second peripheral source/drain being disposed within the peripheral active regions;
a first through-insulating pattern that penetrates through the semiconductor body;
a second through-insulating pattern that penetrates through the semiconductor body and that is spaced apart from the first through-insulating pattern;
a plurality of first through-plugs that penetrate through the first through-insulating pattern and that are spaced apart from each other in a horizontal direction; and
a plurality of second through-plugs that penetrate through the second through-insulating pattern and that are spaced apart from each other in the horizontal direction, and
wherein the number of the first through-plugs is different from the number of the second through-plugs.

16. The semiconductor device of claim 15, wherein the first structure includes:
active patterns that extend in a first horizontal direction;
bit lines that contact the active patterns and that extend in the vertical direction;
gate electrodes that intersect the active patterns and extend in a second horizontal direction that intersects the first horizontal direction; and
gate pads that extend from the gate electrodes, that are spaced apart from each other in the vertical direction, and that are arranged in a staircase shape,
wherein the plurality of first through-plugs are connected to the bit lines, and
wherein the plurality of second through-plugs are connected to the gate pads.

17. The semiconductor device of claim 16, wherein the cell routing interconnection structure includes bit line contact plugs disposed on the bit lines and gate contact plugs disposed on the gate pads, and
a gap between the plurality of first through-plugs is less than a gap between the plurality of second through-plugs.

18. The semiconductor device of claim 17, wherein the first through-insulating pattern and the second through-insulating pattern include a dielectric material having a dielectric constant lower than a dielectric constant of SiO₂.

19. The semiconductor device of claim 15, wherein a lower surface of the rear insulating layer is disposed at a lower level than a level of a lower surface of each of the plurality of first through-plugs and a lower surface of each of the plurality of second through-plugs.

20. A semiconductor device comprising:
a first structure that includes a memory cell region and a pad region adjacent to the memory cell region, the first structure having an upper surface on which cell bonding pads are disposed; and
a second structure that includes a peripheral circuit region that overlaps the first structure in a vertical direction, the second structure having a lower surface on which peripheral bonding pads that are bonded to the cell bonding pads are disposed,
wherein the first structure includes:
memory cells disposed in the memory cell region, each memory cell including a memory cell transistor and an information storage structure connected to the memory cell transistor; and
a cell routing interconnection structure electrically connected to the memory cells,
wherein the second structure includes:
a semiconductor body;
a rear insulating layer below the semiconductor body;
element isolation patterns that define peripheral active regions of the semiconductor body; and
peripheral transistors, each including a first peripheral source/drain, a second peripheral source/drain, a peripheral channel region between the first and peripheral source/drain and the second peripheral source/drain, and a peripheral gate disposed on the peripheral channel region, the first peripheral source/drain and the second peripheral source/drain being disposed in the peripheral active regions;
a first through-insulating pattern that penetrates through the semiconductor body and that overlaps the memory cell region in the vertical direction;
a second through-insulating pattern that penetrates through the semiconductor body and that overlaps the pad region in the vertical direction;
a plurality of first through-plugs that penetrate through the first through-insulating pattern and that are spaced apart from each other in a horizontal direction; and
a plurality of second through-plugs that penetrate through the second through-insulating pattern and that are spaced apart from each other in the horizontal direction, and
wherein a gap between the plurality of first through-plugs is different from a gap between the plurality of second through-plugs.
